(19) United States
(12) Patent Application Publication
(10) Pub. No.: US 2016/0106188 A1
(43) Pub. Date: Apr. 21, 2016

(54) PROTECTION DEVICE FOR A MOBILE TERMINAL

(71) Applicant: Golden Vast Macao Commercial Offshore Limited, Macau (CN)

(72) Inventor: KwokFong Wong, Heshan City (CN)

(21) Appl. No.: 14/516,950

(22) Filed: Oct. 17, 2014

(51) Int. Cl. A45C 11/00; A45F 5/00; H05K 5/00

(52) U.S. Cl. CPC A45C 11/00; H05K 5/0086; A45F 5/00; A45C 2011/002

(57) ABSTRACT

The invention discloses a protection device for a mobile terminal and relates to the field of the communication technology. The protection device comprises an upper housing body and a lower housing body. The upper housing body has a first hollow portion at a middle portion thereof, and the upper housing body is provided with a combination part perpendicular to a lower surface of the upper housing body at a bottom thereof. An upper side surrounding edge, a lower side surrounding edge, a left side surrounding edge and a right side surrounding edge perpendicular to a lower surface of the lower housing body respectively are provided on an upper side, a lower side, a left side and a right side of the lower housing body, a groove for clamping with the upper housing body is opened on an upper end of each of the upper side surrounding edge, the left side surrounding edge and the right side surrounding edge, and a gap corresponding to the combination part is opened on the lower side surrounding edge such that the combination part can be integrated with the lower side surrounding edge through the gap. The lower housing body has a second hollow portion on a lower surface thereof, and an external device is detachably disposed in the second hollow portion. The protection device for a mobile terminal of the invention is convenient in assembly and disassembly.

### FIELD OF THE INVENTION

The invention relates to the field of communication technology, and more particularly a protection device for a mobile terminal.

### DESCRIPTION OF THE RELATED ART

With the rapid development of communication technology, various mobile terminals, such as a mobile phone, have more and more powerful functionalities, and thus become necessary tools in daily life of people. In order to protect a mobile terminal and avoid abrasion and damage of the mobile terminal, generally a protection device is disposed outside of the mobile terminal by a user such that the mobile terminal can be protected.

However, currently, an existing protection device for a mobile terminal is one piece, and thus has the disadvantages of inconvenient assembly and disassembly, and single function.

### SUMMARY OF THE INVENTION

In order to solve the problem of the prior art, the invention provides a protection device for a mobile terminal.

For the above purpose, the invention utilizes the following technical solution: in one aspect, the invention provides a protection device for a mobile terminal, comprising an upper housing body and a lower housing body.
wherein the upper housing body has a first hollow portion at a middle portion thereof, and is provided with a combination part perpendicular to a lower surface of the upper housing body at a bottom thereof; and
wherein the lower housing body comprises an upper side surrounding edge, a lower side surrounding edge, a left side surrounding edge and a right side surrounding edge which are perpendicular to a lower surface of the lower housing body on an upper side, a lower side, a left side and a right side thereof respectively, a groove for clamping with the upper housing body is opened on an upper end of each of the upper side surrounding edge, the left side surrounding edge and the right side surrounding edge, and a gap corresponding to the combination part is opened on the lower side surrounding edge such that the combination part is enabled to be integrated with the lower side surrounding edge through the gap, the lower housing body has a second hollow portion on a lower surface thereof, and an external device is detachably disposed in the second hollow portion.

By utilizing the above technical solution, as compared with the prior art the invention has the following advantages: the protection device of the invention comprises an upper housing body and a lower housing body, and the upper housing body can be pushed to or pulled out of the grooves of the lower housing body, such that the upper housing body is integrated with or detached from the lower housing body, and thus the protection device of the invention is convenient in assembly and disassembly. Furthermore, the protection device is provided with a detachable external device, and thus further functionalities can be achieved.

### BRIEF DESCRIPTION OF THE DRAWINGS

In order to illustrate the technical solution of the invention more clearly, the drawings used in preferred embodiments of the present invention will now be described simply. Fr a person skilled in the art, It is obvious that the drawings described hereinafter are only some of embodiments, and many equivalent drawings can be obtained according to these drawings without any creative works.

FIG. 1 is a first schematic view of an upper housing body of a protection device for a mobile terminal according to an embodiment 1 of the invention;

FIG. 2 is a second schematic view of the upper housing body of the protection device for a mobile terminal according to the embodiment 1 of the invention;

FIG. 3 is a first schematic view of a lower housing body of the protection device for a mobile terminal according to the embodiment 1 of the invention;

FIG. 4 is a second schematic view of the lower housing body of the protection device for a mobile terminal according to the embodiment 1 of the invention;

FIG. 5 is a first perspective view of the protection device for a mobile terminal according to the embodiment 1 of the invention;

FIG. 6 is a second perspective view of a protection device for a mobile terminal according to the embodiment 1 of the invention;

FIG. 7 is a schematic view of an external device according to the embodiment 1 of the invention;

FIG. 8 is a third schematic view of the lower housing body of the protection device for a mobile terminal according to the embodiment 1 of the invention;

FIG. 9 is a first schematic view showing the connection of the lower housing body and the external device of the protection device of a mobile terminal according to the embodiment 1 of the invention;

FIG. 10 is a second schematic view showing the connection of the lower housing body and the external device of the protection device of a mobile terminal according to the embodiment 1 of the invention;

FIG. 11 is a fourth schematic view of the lower housing body of the protection device for a mobile terminal according to the embodiment 1 of the invention;

FIG. 12 is a third perspective view of the protection device for a mobile terminal according to the embodiment 1 of the invention;

FIG. 13 is a fourth perspective view of the protection device for a mobile terminal according to the embodiment 1 of the invention;

FIG. 14 is a fifth schematic view of the lower housing body of the protection device for a mobile terminal according to the embodiment 1 of the invention;

FIG. 15 is a sixth schematic view of the lower housing body of the protection device for a mobile terminal according to the embodiment 1 of the invention;

FIG. 16 is a fifth perspective view of a protection device for the mobile terminal according to the embodiment 1 of the invention;

FIG. 17 is a sixth perspective view of the protection device for a mobile terminal according to the embodiment 1 of the invention.

### DETAILED DESCRIPTION OF THE INVENTION

In order to make the object, the technical solution and advantages of the invention more clearly, preferred embodiments of the invention will be described more detailedly hereinafter in connection with accompanying drawings.

### Embodiment 1

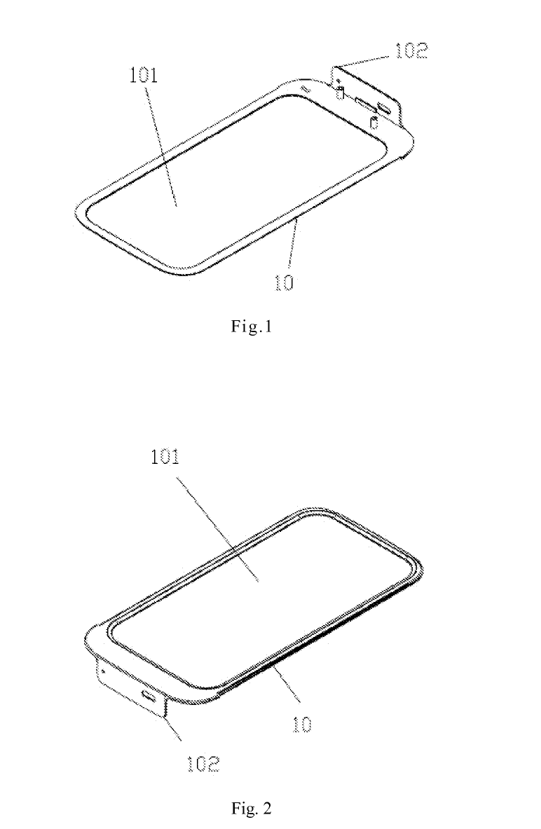

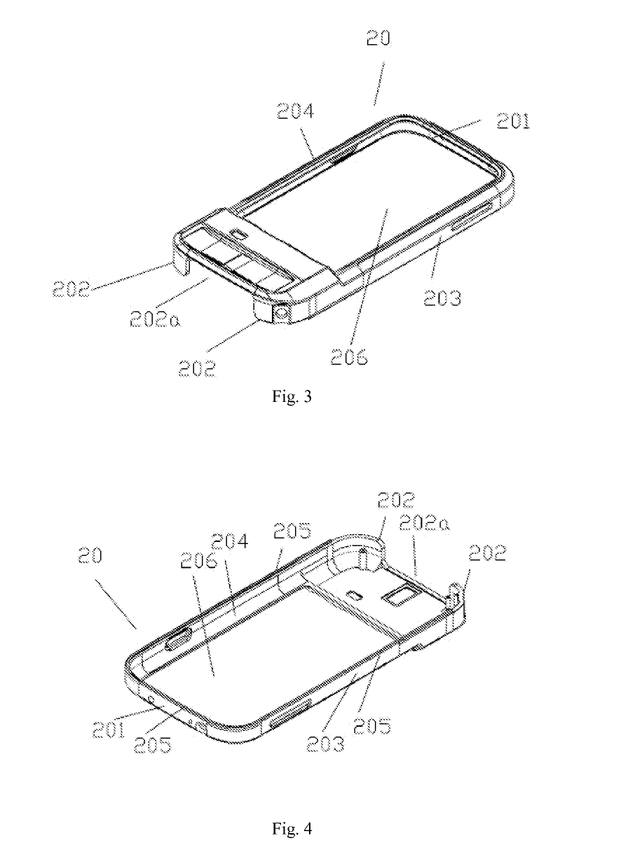

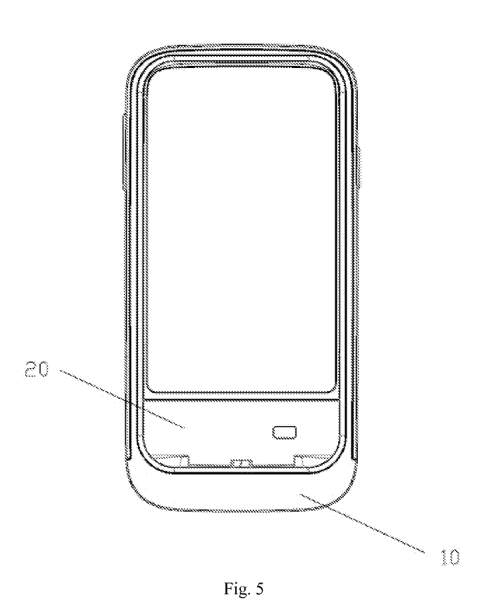

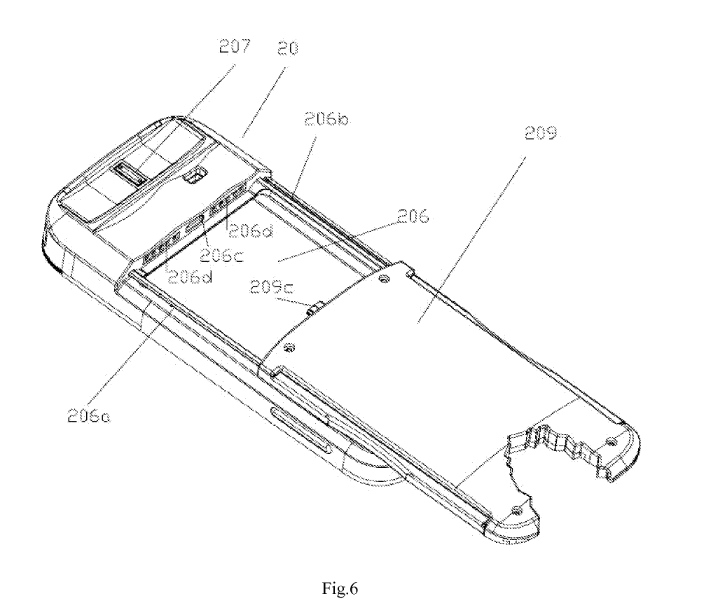

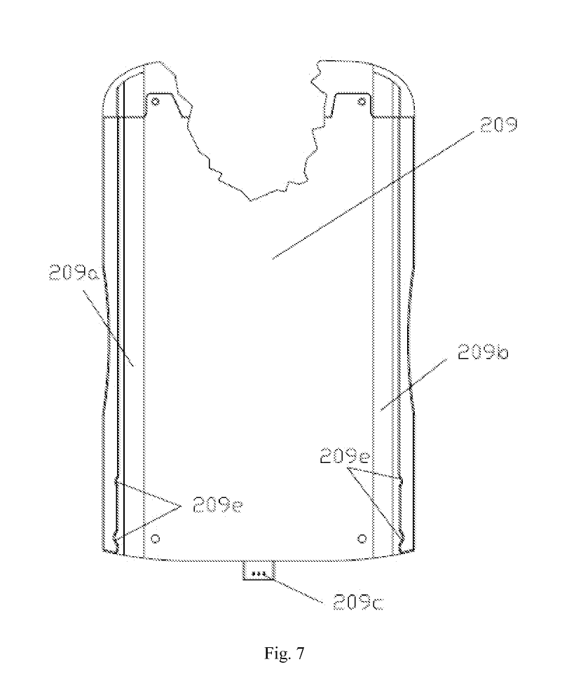

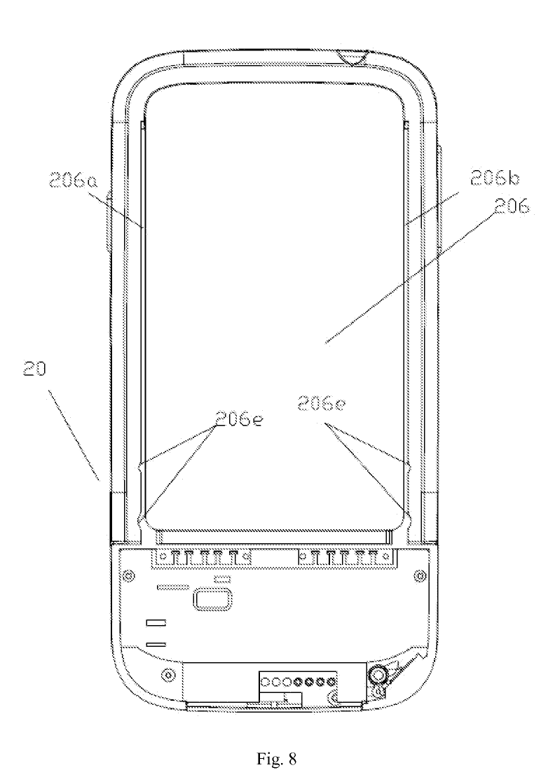

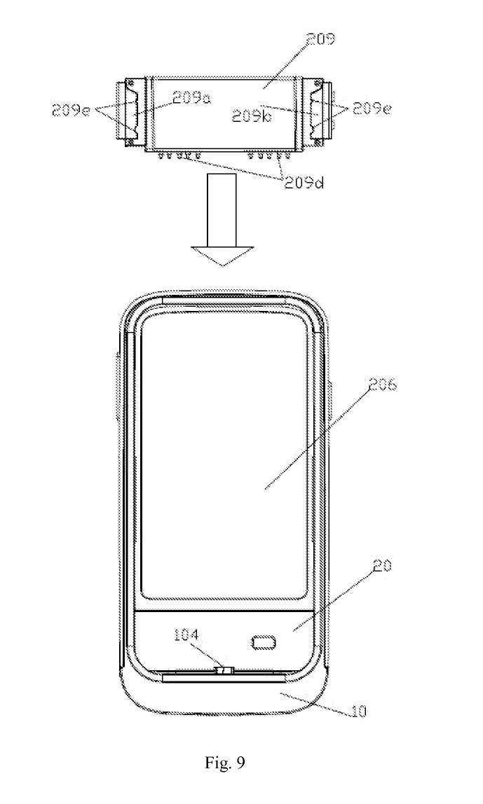

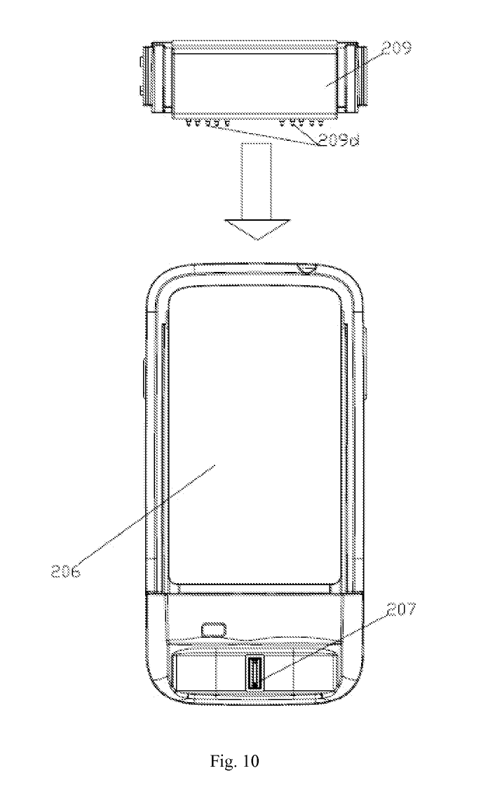

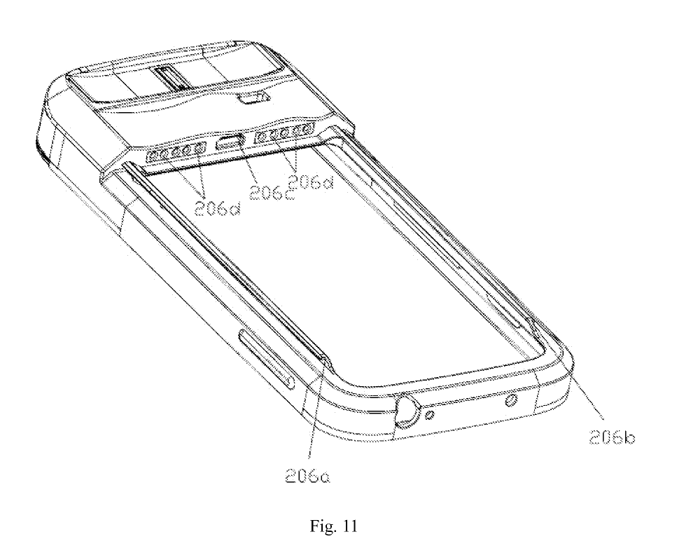

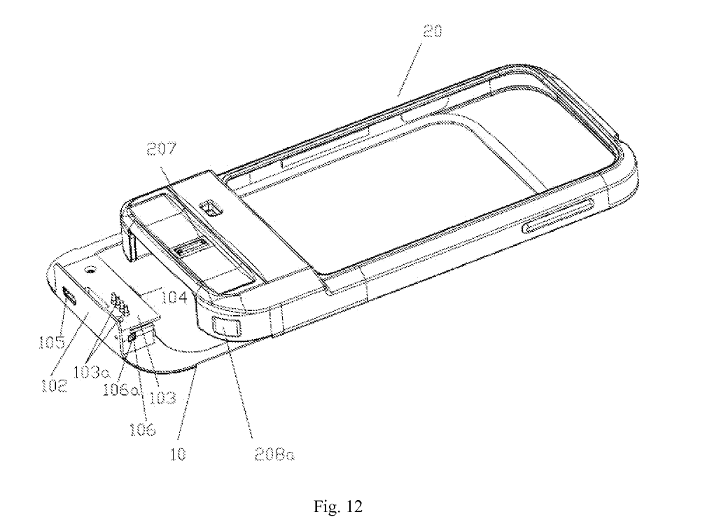

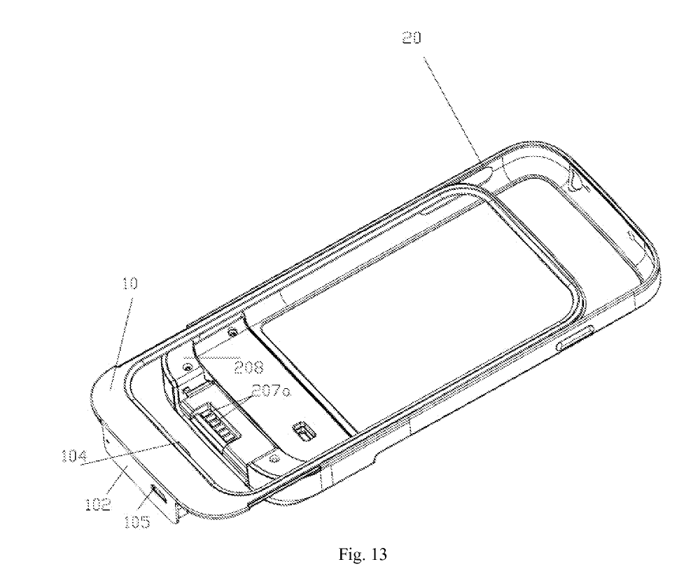

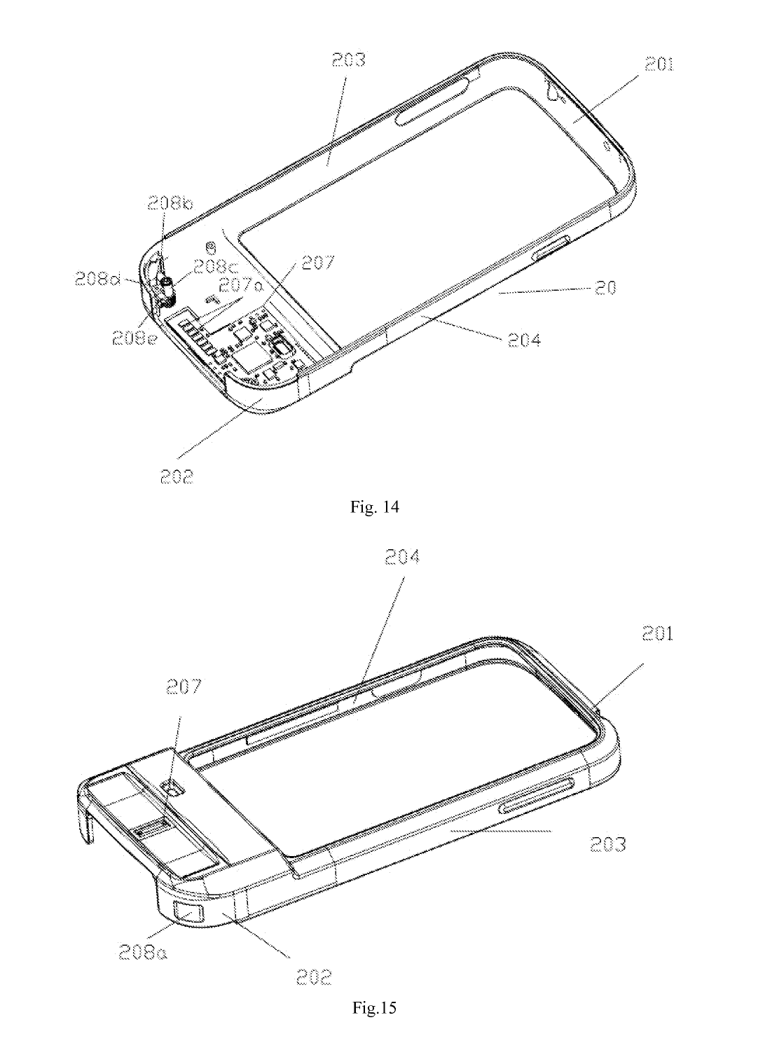

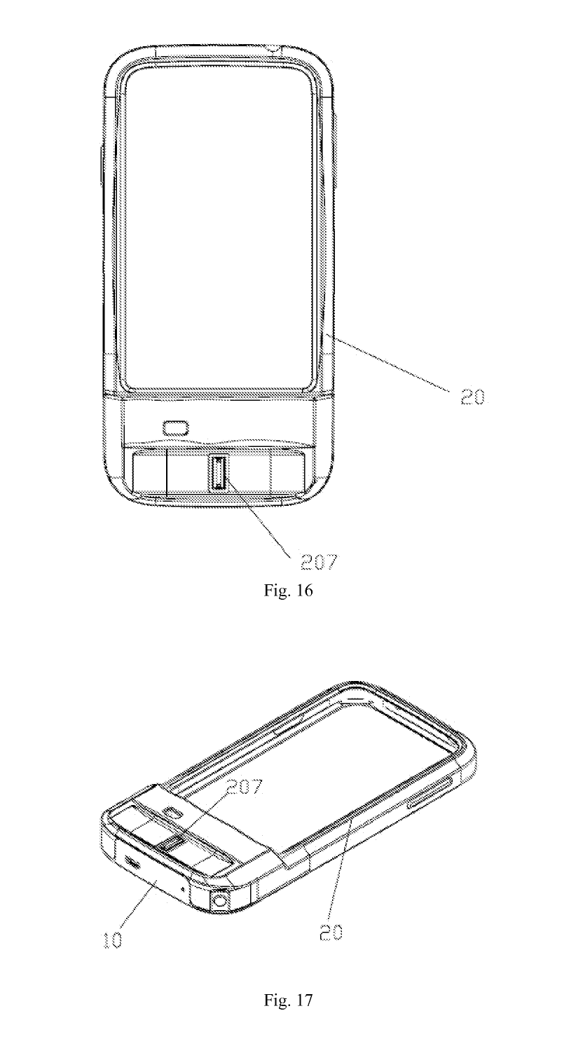

The embodiment 1 of the invention provides a protection device for a mobile terminal, as shown in FIGS. 1-17, the protection device comprises an upper housing body 10 and a lower housing body 20.

The upper housing body 10 has a first hollow portion 101 at a middle portion thereof, and the upper housing body 10 is provided with a combination part 101 at a bottom thereof, the combination part 101 is perpendicular to a lower surface of the upper housing body 10.

An upper side surrounding edge 201, a lower side surrounding edge 202, a left side surrounding edge 203 and a right side surrounding edge 204 perpendicular to the lower surface of the lower housing body 20 respectively are provided on an upper side, a lower side, a left side and a right side of the lower housing body 20. a groove 205 for clamping with the upper housing body 10 is opened on an upper end of each of the upper side surrounding edge, the left side surrounding edge and the right side surrounding edge, and a gap 202a corresponding to the combination part 102 is opened on the lower side surrounding edge 202 such that the combination part 102 can be integrated with the lower side surrounding edge 202 through the gap 202a. The lower housing body 20 has a second hollow portion 206 at a lower surface thereof, and an external device 209 is detachably disposed in the second hollow portion 206.

The size of the first hollow portion 101 of the upper housing body 10 is corresponding to the size of the screen of a mobile terminal which utilizes the protection device, and thus can be designed according to the size of the screen of the mobile terminal.

The size of the second hollow portion 206 of the lower housing body 20 may be designed according to the size of the back of the mobile terminal. The second hollow portion 206 is provided on the lower surface of the lower housing 20, thus, the back of the mobile terminal may be exposed, and this can improve the aesthetic feeling and the experience of a user.

Specifically, the upper housing body 10 can be pushed to or pulled out of the grooves 205 of the lower housing body 20, such that the upper housing body 10 is integrated with or detached from the lower housing body 20.

Preferably, a first clamping column 206a and a second clamping column 206b respectively are provided at a left side and a right side of the second hollow portion 206, and a first clamping groove 209a and a second clamping groove 209b corresponding to the first clamping column 206a and the second clamping column 206b respectively are opened on a left side and a right side of the external device 209, the first clamping column 206a and the second clamping column 206b respectively can slide into the first clamping groove 209a and the second clamping groove 209b such that the external device 209 is integrated with the second hollow portion 206, and the first clamping column 206a and the second clamping column 206b respectively can slide out of the first clamping groove 209a and the second clamping groove 209b such that the external device is detached from the second hollow portion 206.

Specifically, the first clamping column and the second clamping column are pushed into the first clamping groove and the second clamping groove of the external device 209, and the external device 209 is drawn in the up-down direction such that the first clamping column and the second clamping column slide to or slide out of the first clamping groove and the second clamping groove of the external device 209, and the external device 209 is fixed on the protection device for a mobile terminal, or detached from the housings of the protection device for a mobile terminal.

Preferably, a first communication interface 209c is provided on an upper side of the external device 209 and a second communication interface 206c corresponding to the first communication device 209c is provided on an upper side of the second hollow portion 206, when the first clamping column 206a and the second clamping column 206b respectively slide into the first clamping groove 209a and the second clamping groove 209b such that the upper side of the external device 209 is integrated with the upper side of the second hollow portion 206, the first communication interface 209c is connected with the second communication interface 206c.

The first communication interface and the second communication interface may be a USB interface, and also may be a Micro USB interface, or other various interfaces usually utilized in the existing mobile terminals.

Preferably, a plurality of first connection points 209d are provided on an upper side of the external device 209, and a plurality of second connection points 206d respectively corresponding to the plurality of first connection points 209d are provided on an upper side of the second hollow portion 206, when the first clamping column 206a and the second clamping column 206b respectively slide into the first clamping groove 209a and the second clamping groove 209b such that the upper side of the external device 209 is integrated with the upper side of the second hollow portion 206, the first connection points 209d are connected with the second connection points 206d.

Preferably, a clamping point 206e is provided on each of the first clamping column 206a and the second clamping column 206b, and a clamping site 209e corresponding to the clamping point 206e is provided on each of the first clamping groove 209a and the second clamping groove 209b.

Specifically, when the first clamping column 206a and the second clamping column 206b respectively slide into the first clamping groove 209a and the second clamping groove 209b such that the upper side of the external device 209 is integrated with the upper side of the second hollow portion 206, the clamping points 206e are clamped with the clamping sites 209e, and the external device 209 are firmly fixed on the housings of the protection device of a mobile terminal, that is to say, the fixation of the external device 209 is reinforced by means of the clamping points 206e and the clamping sites 209e.

Preferably, the external device comprises at least one of a buckle, a mobile power source, a wireless charging device, a camera lens, a sounding device, an electronic larynx, a storage device, a data transmission device and a light-emitting device.

Specifically, the external device 209 may comprises a buckle for assisting a user in carrying the mobile terminal, and the buckle is designed to have the advantages of fashionable appearance, convenience in carrying and using. The external device 209 may comprise a micro mobile power source, when the power of the mobile terminal of a user is running low, the mobile terminal is connected to the mobile power source to provide power for the mobile terminal for 1-3 hours, and this can temporarily solve the problem of power shortage. The external device 209 may comprise a wireless charging device, and the charging function of the wireless charging device for the mobile terminal can be achieved in connection with the wireless charging module in the mobile terminal. The external device 209 may comprise a camera lens with a coil, and 3D creation can be achieved by means of the camera carried by the mobile terminal and the applications in the mobile terminal, if a user doesn't want to make a 3D file, the camera carried by the mobile terminal can be replaced by an external camera to shoot a more beautiful and clear photograph. The external device 209 may comprise a sounding device, a user can use the sounding device to chat or perform other voice applications, by setting the device in various means, many lovely or different voices can be sounded, and besides having funny, the sounding device also can be used when a user doesn't want her/his voice is recognized by others, for example, a user sounds a male voice, the resulting voice is a female voice or animal's voice or the like. The external device 209 may comprises an electronic larynx, this provides an auxiliary tool for a user who is suffering from a throat cancer or does not want to speak, in use, after the electronic larynx is fixed, the protection device for a mobile terminal is placed on the skin near the esophagus, a corresponding voice can be sounded by means of the vibration of a user who desires to speak. The external device 209 may comprise a storage device, and the storage device will expand the storage function of the mobile terminal after being connected with the mobile terminal. The external device 209 may comprise a data transmission device, and a user can utilize the touch screen of the mobile terminal to achieve the rapid data transmission in different means (such as one point-to-one point, one point-to-multipoints) by means of different gestures. The external device 209 may comprise a shining light-emitting device, and when the mobile terminal is connected, or the communication or other applications are performed, a user can emits a personalized message (this message can be set in the applications of the mobile terminal according to the preference of the user), then the message is displayed on the light-emitting device.

It shall be noted that, the external device 209 is not limited to the above types, and according to the desired functions of a user, the external device 209 can be designed in different means to meet the requirements of the user.

It shall be noted that, the appearance of the external device 209 is designed such that the external device 209 is very close to the protection device of the mobile terminal, and the size and thickness are not limited, wherein the length is preferably corresponding to the size of the mobile terminal, the width is primarily designed for the comfort degree, and the thickness may be in the range of 1-5 cm.

Preferably, a connection device 103 is provide on a back side of the combination part 102, a male communication interface 104 corresponding to a communication interface of the mobile terminal is provided on an upper side of the connection device 103, and a female communication interface 105 is provided on a front side of the combination part 102, the female communication interface 105 is communicated with the male communication interface 104 by means of the connection device 103.

The male communication interface 104 and the female communication interface 105 may be a USB interface, and also may be a Micro USB interface, or other various interface usually utilized in the existing mobile terminals.

Specifically, the male communication interface 104 is connected with the communication interface of the mobile terminal and the female communication interface 105 is connected with other devices, such that the mobile terminal can be connected with other devices without disassembly of the protection device of the mobile terminal, this is very convenient for a user.

Preferably, a fingerprint recognition device 207 is disposed on a part of the lower housing body 20 below the second hollow portion 206.

When the fingerprint recognition device 207 is disposed on a part of the lower housing body 20 below the second hollow portion 206, the size of the second hollow portion 206 can be designed according to the size of the back of the mobile terminal and the fingerprint recognition device 207.

Preferably, multiple contact points 207a are provided on a lower surface of the fingerprint recognition device 207, and multiple coupling points 103a corresponding to the multiple contact points 207a are provided on a lower surface of the connection device 103.

Specifically, when the upper housing body 10 is coupled with the lower housing body 20, the contact points 207a are connected with the coupling points 103a, thus, the fingerprint recognition device 207 in the lower housing body 20 can be electrified, and the fingerprint recognition device 207 can perform authentication using the fingerprint information of a user, such that the user can use the various applications associated with the fingerprint, such as the decryption and encryption of documents, pictures and media.

Preferably, a main clamping device 208 for clamping the upper housing body 10 with the lower housing body 20 is provided on a back side of the lower side surrounding edge 202 of the lower housing body 20, and an auxiliary clamping device 106 for assisting clamping of the main clamping device corresponding to the main clamping device 208 is provided on the connection device 103 on the combination part 102 of the upper housing body 10.

Preferably, the main clamping device 208 comprises a control switch 208a, a first moving rod 208b, an elastic mechanism 208c, a second moving rod 208d and a clamping rod 208e.

The control switch is embedded in the lower side surrounding edge 202. The first moving rod 208b is disposed at an inner side of the lower side surrounding edge 202. One end of the first moving rod 208b is connected with the control switch 208a, and the other end of the first moving rod 208b is connected with the elastic mechanism 208c which is disposed on the lower surface of the lower housing body 20. One end of the second moving rod 208d is connected with the elastic mechanism 208c, and the other end of the second moving rod 208d is connected with the clamping rod 208e.

The auxiliary clamping device 106 specially is a recess 106a corresponding to the clamping rod 208e for clamping with the clamping rod 208e.

Specifically, the upper housing body 10 can be locked or unlocked with the lower housing body 20 by means of the main clamping device 208 and the auxiliary clamping device 106. When a user pushes the upper housing body 10 to the grooves 205 of the lower housing body 20 such that the upper housing body 10 is coupled with the lower housing body 20, the clamping rod 208e is inserted into the recess 106a, the second moving rod 208d, the elastic mechanism 208c and the first moving rod 208b push the control switch 208a to bounce off such that the upper housing body 10 is locked with the lower housing body 20. When the user presses down the control switch 208a, the first moving rod 208b, the elastic mechanism 208c and the second moving rod 208d drive the clamping rod 208e to depart from the recess 106a, and the bottom of the upper housing body 10 bounces off such that the upper housing body 10 is unlocked with the lower housing body 20, then the upper housing body 10 is pulled out of the grooves 205 of the lower housing body 20 such that the upper housing body 10 is detached from the lower housing body 20.

Preferably, the material of the upper housing body 10 is plastic, silica gel, metal or the like, and the material of the lower housing body 20 is plastic, silica gel, metal or the like.

The metal may be aluminum or other types of metal, and is not limited herein. the protection device of the invention comprises an upper housing body 10 and a lower housing body 20, and the upper housing body 10 can be pushed to or pulled out of the grooves 205 of the lower housing body 20, such that the upper housing body 10 is integrated with or detached from the lower housing body 20, and thus the protection device of the invention is convenient in assembly and disassembly. Furthermore, the protection device is provided with a detachable external device, and thus other functionalities can be achieved by means of the external device. The upper housing body 10 can be pushed to or pulled out of the grooves 205 of the lower housing body 20, such that the upper housing body 10 is integrated with or detached from the lower housing body 20, thus, any damages (such as, scratch) to the surface of the mobile terminal will be avoided during the assembly or disassembly of the protective device, this is convenient for the user. The upper housing body 10 is locked with the lower housing body 20 by means of the control switch, and thus the upper housing body 10 is contacted with the lower housing body 20 more stably.

The numberings of the embodiments are given only for description, regardless of the quality of the embodiments.

The above description only relates to preferred embodiments of the invention, is not intended for limiting of the invention. Any variations, equivalent substitutions, improvements within the spirit and scope of the invention are contained in the extent of protection of the invention.

1. A protection device for a mobile terminal, comprising:
an upper housing body, the upper housing body having a first hollow portion at a middle portion thereof, and the upper housing body being provided with a combination part perpendicular to a lower surface of the upper housing body at a bottom thereof; and
a lower housing body comprising an upper side surrounding edge, a lower side surrounding edge, a left side surrounding edge and a right side surrounding edge which are perpendicular to a lower surface of the lower housing body on an upper side, a lower side, a left side and a right side thereof respectively, wherein a groove for clamping with the upper housing body is opened on an upper end of each of the upper side surrounding edge, the left side surrounding edge and the right side surrounding edge, and a gap corresponding to the combination part is opened on the lower side surrounding edge such that the combination part is enabled to be integrated with the lower side surrounding edge through the gap, the lower housing body having a second hollow portion on a lower surface thereof, and an external device being detachably disposed in the second hollow portion.

2. The protection device for a mobile terminal as claimed in claim 1, wherein a first clamping column and a second clamping column respectively are provided on a left side and a right side of the second hollow portion, and a first clamping groove and a second clamping groove corresponding to the first clamping column and the second clamping column respectively are opened on a left side and a right side of the external device, the first clamping column and the second clamping column respectively can slide into the first clamping groove and the second clamping groove such that the external device is integrated with the second hollow portion, and the first clamping column and the second clamping column respectively can slide out of the first clamping groove and the second clamping groove such that the external device is detached from the second hollow portion.

3. The protection device for a mobile terminal as claimed in claim 2, wherein a first communication interface is provided on an upper side of the external device and a second communication interface corresponding to the first communication device is provided on an upper side of the second hollow portion, when the first clamping column and the second clamping column respectively slide into the first clamping groove and the second clamping groove such that the upper side of the external device is integrated with the upper side of the second hollow portion, the first communication interface is connected with the second communication interface.

4. The protection device for a mobile terminal as claimed in claim 2, wherein a plurality of first connection points are provided on an upper side of the external device, and a plurality of second connection points respectively corresponding to the plurality of first connection points are provided on an upper side of the second hollow portion, when the first clamping column and the second clamping column respectively slide into the first clamping groove and the second clamping groove such that the upper side of the external device is integrated with the upper side of the second hollow portion, the first connection points are connected with the second connection points.

5. The protection device for a mobile terminal as claimed in claim 2, wherein a clamping point is provided on each of the first clamping column and the second clamping column, and a clamping site corresponding to the clamping point is provided on each of the first clamping groove and the second clamping groove.

6. The protection device for a mobile terminal as claimed in claim 1, wherein the external device comprises at least one of a buckle, a mobile power source, a wireless charging device, a camera lens, a sounding device, an electronic larynx, a storage device, a data transmission device and a light-emitting device.

7. The protection device for a mobile terminal as claimed in claim 1, wherein a connection device is provide on a back side of the combination part, a male communication interface corresponding to a communication interface of the external device being provided on an upper side of the connection device, and a female communication interface being provided on a front side of the combination part, the female communication interface being communicated with the male communication interface by means of the connection device.

8. The protection device for a mobile terminal as claimed in claim 7, wherein a fingerprint recognition device is disposed on a part of the lower housing body below the second hollow portion.

9. The protection device for a mobile terminal as claimed in claim 8, wherein multiple contact points are provided on a lower surface of the fingerprint recognition device, and multiple coupling points corresponding to the multiple contact points are provided on a lower surface of the connection device.

10. The protection device for a mobile terminal as claimed in claim 7, wherein a main clamping device for clamping the upper housing body with the lower housing body is provided on a back side of the lower side surrounding edge of the lower housing body, and an auxiliary clamping device for assisting clamping of the main clamping device corresponding to the main clamping device is provided on the connection device on the combination part of the upper housing body.

11. The protection device for a mobile terminal as claimed in claim 10, wherein the main clamping device comprises:
a control switch embedded in the lower side surrounding edge;
an elastic mechanism disposed on the lower surface of the lower housing body;
a first moving rod disposed at an inner side of the lower side surrounding edge, one end of which is connected with the control switch, and the other end of which is connected with the elastic mechanism;
a clamping rod; and
a second moving rod, one end of which is connected with the elastic mechanism, and the other end of which is connected with the clamping rod; and
the auxiliary clamping device specially is a recess corresponding to the clamping rod for clamping with the clamping rod.

12. The protection device for a mobile terminal as claimed in claim 5, wherein the material of the upper housing body is plastic, silica gel or metal, and the material of the lower housing body is plastic, silica gel or metal.

13. The protection device for a mobile terminal as claimed in claim 3, wherein a clamping point is provided on each of the first clamping column and the second clamping column, and a clamping site corresponding to the clamping point is provided on each of the first clamping groove and the second clamping groove.

14. The protection device for a mobile terminal as claimed in claim 4, wherein a clamping point is provided on each of the first clamping column and the second clamping column, and a clamping site corresponding to the clamping point is provided on each of the first clamping groove and the second clamping groove.

15. The protection device for a mobile terminal as claimed in claim 2, wherein the external device comprises at least one of a buckle, a mobile power source, a wireless charging device, a camera lens, a sounding device, an electronic larynx, a storage device, a data transmission device and a light-emitting device.

16. The protection device for a mobile terminal as claimed in claim 3, wherein the external device comprises at least one of a buckle, a mobile power source, a wireless charging device, a camera lens, a sounding device, an electronic larynx, a storage device, a data transmission device and a light-emitting device.

17. The protection device for a mobile terminal as claimed in claim 4, wherein the external device comprises at least one of a buckle, a mobile power source, a wireless charging device, a camera lens, a sounding device, an electronic larynx, a storage device, a data transmission device and a light-emitting device.

18. The protection device for a mobile terminal as claimed in claim 2, wherein a connection device is provide on a back side of the combination part, a male communication interface corresponding to a communication interface of the external device being provided on an upper side of the connection device, and a female communication interface being provided on a front side of the combination part, the female communication interface being communicated with the male communication interface by means of the connection device.

19. The protection device for a mobile terminal as claimed in claim 3, wherein a connection device is provide on a back side of the combination part, a male communication interface corresponding to a communication interface of the external device being provided on an upper side of the connection device, and a female communication interface being provided on a front side of the combination part, the female communication interface being communicated with the male communication interface by means of the connection device.

20. The protection device for a mobile terminal as claimed in claim 4, wherein a connection device is provide on a back side of the combination part, a male communication interface corresponding to a communication interface of the external device being provided on an upper side of the connection device, and a female communication interface being provided on a front side of the combination part, the female communication interface being communicated with the male communication interface by means of the connection device.
